(19) United States
(12) Patent Application Publication
(10) Pub. No.: US 2009/0010457 A1
(43) Pub. Date: Jan. 8, 2009

(54) AUDIO SIGNAL AMPLIFYING CIRCUIT AND ELECTRONIC DEVICE USING THE SAME

(75) Inventors: Hideki Munenaga, Kyoto (JP); Takeshi Onodera, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 11/816,361

(22) PCT Filed: Dec. 22, 2005
(86) PCT No.: PCT/JP2005/023640

§ 371 Date: Aug. 15, 2007

(30) Foreign Application Priority Data
Feb. 17, 2005 (JP) 2005-040931

(51) Int. Cl. H03F 21/00

(52) U.S. Cl. 381/120

(57) ABSTRACT

In an audio signal amplifying circuit, a main amplifier and a sub amplifier amplify an audio signal. The sub amplifier is disposed in parallel with the main amplifier and also is set to have a lower driving capability than the main amplifier. A control unit controls the on and off of the main amplifier. The control unit turns the main amplifier off when it is determined that the audio signal is in a mute state. An audio signal amplified by the main amplifier and the sub amplifier passes through a low-pass filter to be converted into an analog signal and is output to a speaker.

### BACKGROUND OF THE INVENTION

1. Field of the Invention

The present invention relates to a technique of amplifying an audio signal, and more particularly to an audio signal amplifying circuit which drives a speaker or an earphone.

2. Description of the Related Art

In accordance with the development of the LSI technique of recent years, in a digital audio represented by a CD player, an MD player or the like, a one-bit DAC (Digital Analog Converter) is used for digital signal processing and amplification thereof. In this one-bit DAC, a sound signal is subjected to noise shaping with use of a ΔΣ modulator, and is output as a one-bit PWM signal having been subjected to pulse width modulation PWM (Pulse Width Modulation).

This one-bit PWM signal is amplified to a predetermined level for driving a speaker which is a load. For this purpose, a D-class amplifier capable of obtaining a high efficiency is used. The amplified one-bit PWM signal passes through a post-positioned low-pass filter to become an analog reproduction signal, and is reproduced as a sound from the speaker. For example, the patent document 1 discloses a driver circuit (hereinafter referred to as a signal amplifying circuit in the present specification) which amplifies a digital audio signal using a D-class amplifier.

In such a signal amplifying circuit, as described in FIG. 3 of the patent document 1, a capacitor for prevention of direct current (hereinafter referred to as a DC block capacitor) is disposed on a driving path of the filter and the speaker. By this DC block capacitor, the DC component of the analog audio signal is removed, and a voltage of an alternating current component having a ground potential as a center value is applied to the speaker.

In a signal amplifying circuit using such a D-class amplifier, in a so-called mute state, the duty ratio of the one-bit PWM signal subjected to pulse width modulation and input into the D-class amplifier must be fixed to a constant value. This is because, when the duty ratio is fixed, the output voltage of the post-positioned low-pass filter will be a direct-current voltage, so that the DC component is removed by the DC block capacitor, and the voltage applied to the speaker is fixed to the ground potential. Typically, the duty ratio to be fixed in a mute state is set to be 50% so as to equalize the voltage applied to the speaker in the positive and in the negative.

[PATENT DOCUMENT 1] Japanese Patent Application Laid-Open No. 2001-223537

In such a signal amplifying circuit using a D-class amplifier, in the case of realizing a mute state by fixing the duty ratio, there is a problem in that a high S/N ratio cannot be obtained because of the switching noise or the like that is generated from the D-class amplifier. In order to solve this problem, a method in which a mute transistor is disposed between the input terminal of the speaker and the ground potential, and this mute transistor is turned on in the mute state, can be considered.

However, by this method, the mute transistor must be separately provided, thereby raising a problem of increased circuit scale.

### SUMMARY OF THE INVENTION

The present invention has been made in order to solve such problems, and a general purpose thereof is to provide an audio signal amplifier with reduced noise in the mute state without the need for a mute transistor.

One embodiment of the present invention relates to an audio signal amplifying circuit. This audio signal amplifying circuit includes a main amplifier which amplifies an audio signal, a sub amplifier which is disposed in parallel with the main amplifier and is set to have a lower driving capability than the main amplifier, and a control unit which controls the on and off of the main amplifier. The control unit turns the main amplifier off when it is determined that the audio signal is in a mute state.

The expression “the audio signal is in a mute state” refers to a state in which the reproduced audio signal does not contain a significant signal related to sound, and includes, for example, an interval between tracks and a blank that is set at the head or the tail of the track. According to this embodiment, the noise that is output from the speaker can be reduced by turning the main amplifier off in the mute state and driving the speaker which is the load only with the sub amplifier having a lower driving capability.

The sub amplifier may include an output resistor which is connected in series to an output terminal thereof.

By disposing an output resistor in series to the output terminal, the signal that is output from the sub amplifier is subjected to voltage division before being applied to the speaker, so that the load driving capability of the sub amplifier can be suitably lowered.

A resistance value of the output resistor may be within a range from 2 times to 25 times as large as an impedance of a speaker connected as a load. By adjusting the resistance value of the output resistor in accordance with the impedance of the speaker, the driving capability can be adjusted, whereby the noise in the mute state can be reduced.

A size of a transistor constituting the sub amplifier may be within a range from 1/1.5 times to 1/10 times as large as a size of a transistor constituting the main amplifier. By reducing the size of the transistor constituting the sub amplifier, the electric current supplying capability is lowered, so that the load driving capability can be lowered. Therefore, by adjustment of the transistor size, the noise level can be adjusted.

The audio signal may be a signal subjected to pulse width modulation and output from a ΔΣ modulator. The main amplifier and the sub amplifier may be D-class amplifiers. When the main amplifier and the sub amplifier are D-class amplifiers, the switching operation is carried out with a fixed duty ratio even in a mute state, thereby generating a switching noise. However, by turning the main amplifier off in the mute state, the switching noise is reduced, whereby the noise that is output from the speaker can be reduced.

The term “pulse width modulation” as used herein includes a pulse density modulation that changes the number of times for generating a pulse and other modulations in addition to a pulse width modulation that changes the duty ratio of the on and off while maintaining the frequency to be constant. The term “signal subjected to pulse width modulation” refers to a signal in which the average value over time corresponds to the amplitude of the analog signal.

The audio signal amplifying circuit may further include a ΔΣ modulator which generates a signal subjected to pulse width modulation.

The main amplifier may include a D-class amplifier of CMOS inverter type and a gate driver circuit which controls a gate voltage of a transistor constituting the D-class amplifier. The gate driver circuit may fix the gate voltage of the transistor constituting the D-class amplifier in a state in which the main amplifier is off.

The control unit may monitor the digital audio signal modulated by passing through a predetermined digital signal processing, and may determine that the digital audio signal is in a mute state when a level of the digital audio signal continues to be lower than a predetermined threshold value level for a predetermined period of time or more.

The main amplifier, the sub amplifier, and the control unit may be integrated into one semiconductor integrated circuit.

When they are further constructed with a full CMOS, the degree of integration can be enhanced.

Another embodiment of the present invention is an electronic device. This electronic device includes the above-described audio signal amplifying circuit, a filter which removes a high-frequency component of the audio signal subjected to pulse width modulation and output from the audio signal amplifying circuit, and a speaker which is driven by an output signal of the filter.

According to this embodiment, the noise generated from the speaker in a mute state can be suitably restrained.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram showing a construction of a CD player on which an audio signal amplifying circuit according to an embodiment is mounted;

FIG. 2 is a circuit diagram showing an internal construction of the audio signal amplifying circuit; and

FIG. 3 is a signal waveform view showing an operation state of the audio signal amplifying circuit.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily to the invention.

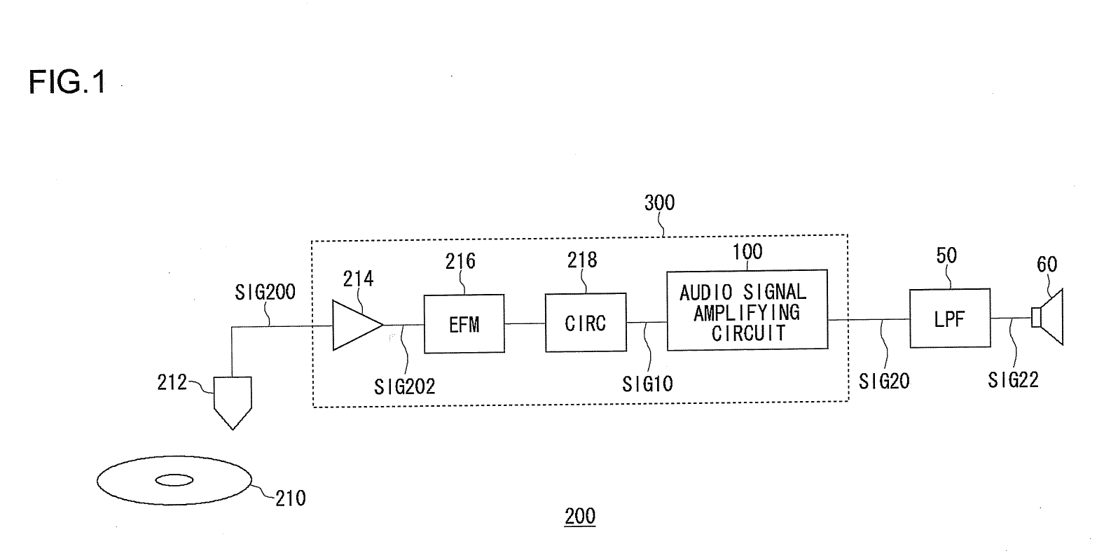

FIG. 1 is a block diagram showing a construction of a CD player on which an audio signal amplifying circuit according to an embodiment of the present invention is mounted.

The CD player 200 includes a disc 210, an optical pickup 212, a DSP (Digital Signal Processor) 300, a low-pass filter 50, and a speaker 60.

The optical pickup 212 radiates laser onto the disc 210, detects the reflected light in accordance with the pits on the disc 210, and converts the optical signal into an electric signal SIG200. The electric signal SIG200 is input into the DSP 300.

The DSP 300 is a digital signal processing circuit including an RF amplifier 214, a demodulating unit 216, an error correction unit 218, and an audio signal amplifying circuit 100. The electric signal SIG200 that has been output from the optical pickup 212 is input into the RF amplifier 214. The RF amplifier 214 amplifies the electric signal SIG200 and outputs the amplified electric signal SIG202 to the demodulating unit 216.

The demodulating unit 216 performs waveform shaping on the electric signal SIG202 to convert it into a pulse series, and performs clock reproduction using a PLL circuit or the like. Thereafter, the pulse series, namely the signal converted into bit data, is demodulated by EFM (Eight to Fourteen Modulation). The data subjected to EFM demodulation are output to the error correction unit 218.

The error correction unit 218 detects errors by the CIRC (Cross Interleave Reed-Solomon Code) method, so as to perform bit error correction.

The digital audio signal SIG10 demodulated by the demodulating unit 216 and subjected to error correction by the error correction unit 218 is output to the audio signal amplifying circuit 100.

The audio signal amplifying circuit 100 performs ΔΣ modulation on the digital audio signal SIG10 to perform noise shaping, and amplifies the audio signal subjected to pulse width modulation with a switching amplifier for output.

The audio signal SIG20 subjected to pulse width modulation and output from the audio signal amplifying circuit 100 is input into the low-pass filter 50. The low-pass filter 50 removes the high-frequency component of the audio signal SIG20 and, after further removing the DC component outputs the resultant to the speaker 60 as an audio signal SIG22 having an analog amplitude component.

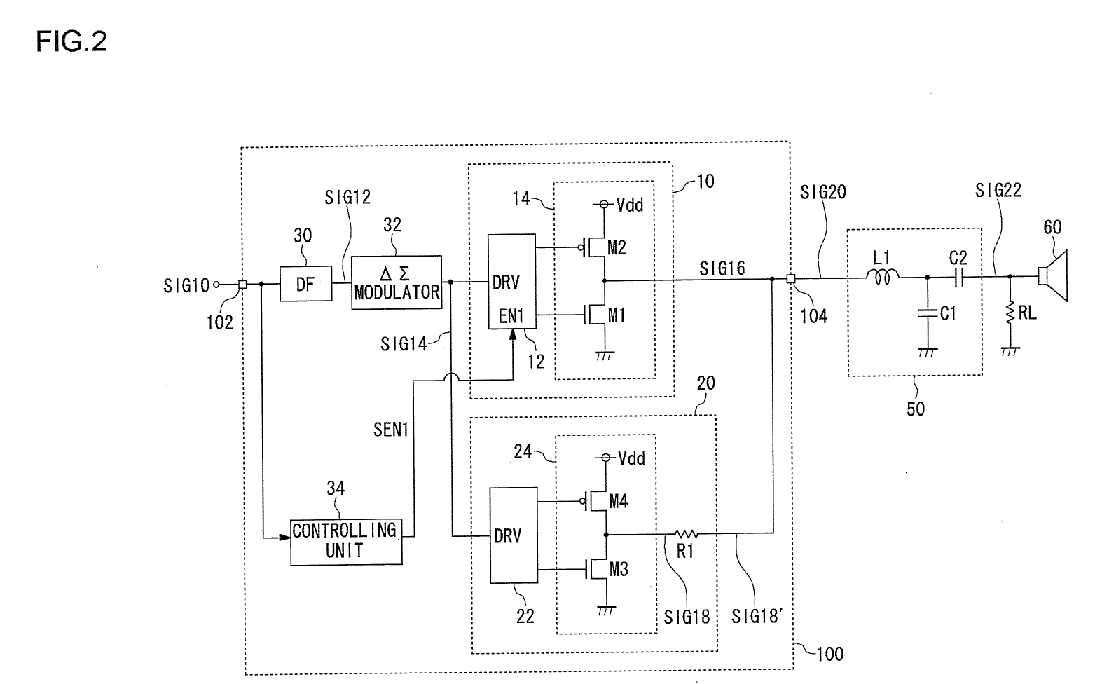

FIG. 2 is a circuit diagram showing an internal construction of the audio signal amplifying circuit 100. FIG. 2 shows the low-pass filter 50 and the speaker 60 together with the audio signal amplifying circuit 100.

The audio signal amplifying circuit 100 includes a main amplifier 10, a sub amplifier 20, a digital filter 30, a ΔΣ modulator 32, and a control unit 34. As described above, the audio signal amplifying circuit 100 is integrated within the DSP 300.

The audio signal SIG10 that is output from the error correction unit 218 is input to the signal input terminal 102 of the audio signal amplifying circuit 100. The audio signal SIG10 that has been input to the signal input terminal 102 is input into the digital filter 30 and the control unit 34.

The digital filter 30 performs digital signal processing on the audio signal SIG10, so as to perform sound volume adjustment and an equalizing process. The audio signal SIG12 subjected to the equalizing process with respect to specific bands by the digital filter 30 is output to the ΔΣ modulator 32.

The ΔΣ modulator 32, which is a ΔΣ modulator of a higher order, for example, of a fifth order, performs noise shaping on the one-bit audio signal SIG12, and outputs it as one-bit audio signal SIG14 subjected to pulse width modulation. The audio signal SIG14 is output to the main amplifier 10 and the sub amplifier 20.

The main amplifier 10 includes a first gate driver circuit 12 and a first D-class amplifier 14.

The first D-class amplifier 14 is a switching amplifier of CMOS inverter type, and includes a first transistor M1 of N-type and a second transistor M2 of P-type which are connected in series between the power supply voltage Vdd and the ground potential.

The gate terminals of the first transistor M1 and the second transistor M2 are connected to the first gate driver circuit 12. The first gate driver circuit 12 drives the first D-class amplifier 14 on the basis of the audio signal SIG14 that has been output from the ΔΣ modulator 32. As a result of this, the audio signal SIG14 is amplified by the main amplifier 10, whereby an audio signal SIG16 subjected to pulse width modulation and having an amplitude changing between 0 V and the power supply voltage Vdd is output.

The first gate driver circuit 12 includes an enabling terminal EN1. The first gate driver circuit 12 stops driving the first D-class amplifier 14 irrespective of the presence or absence of the input of the audio signal SIG14 when the enabling signal SEN1 that is input to the enabling terminal is at a high level. The stoppage of the driving can be realized by fixing the gate voltage of each transistor so that the first transistor M1 and the second transistor M2 are each turned off.

Also, the audio signal SIG14 that is output from the ΔΣ modulator 32 is output to the sub amplifier 20 which is disposed in parallel with the main amplifier 10.

The sub amplifier 20 includes a second gate driver circuit 22 and a second D-class amplifier 24 in the same manner as the main amplifier 10, and further includes an output resistor R1. The second D-class amplifier 24 is a switching amplifier of CMOS inverter type in the same manner as the first D-class amplifier 14, and includes a third transistor M3 and a fourth transistor M4.

The audio signal SIG18 amplified by the second D-class amplifier 24 of the sub amplifier 20 also will be an audio signal subjected to pulse width modulation and having an amplitude changing between 0 V and the power supply voltage Vdd in the same manner as the audio signal SIG16 that is output from the main amplifier 10.

The second D-class amplifier 24 of the sub amplifier 20 is configured to have a lower driving capability than the first D-class amplifier 14 of the main amplifier 10. The capability of driving the load of a D-class amplifier is determined by the current supply capability. Therefore, the transistor size of the third transistor M3 and the fourth transistor M4 constituting the second D-class amplifier 24 is set to be smaller than the transistor size of the first transistor M1 and the second transistor M2 of the first D-class amplifier 14.

The transistor size of the first transistor M1 and the second transistor M2 may be designed so as to be capable of sufficiently driving the speaker 60 at the time of reproducing an ordinary sound signal. In contrast, as will be described later, since the sub amplifier 20 is used in an auxiliary manner, the transistor size of the third transistor M3 and the fourth transistor M4 is set to be about 1/2.5 times as large as the transistor size of the first transistor M1 and the second transistor M2. When the transistor size of the second D-class amplifier 24 is set to be large, the circuit area will be large, leading to increase in the costs. Therefore, the transistor size of the second D-class amplifier 24 is preferably designed to be as small as possible within a range such that a later-mentioned auxiliary function can be exhibited. This size ratio of the transistors can be designed by simulation or by performing an experiment, and is preferably set within a range from 1/1.5 times to 1/10 times.

Further, the sub amplifier 20 includes an output resistor R1 on the output side of the second D-class amplifier 24 so as to lower the driving capability. Since the impedance RL of the speaker 60 is as low as about 2Ω to 32Ω, the voltage amplitude applied to the speaker 60 is lowered by connecting a resistor in series to the output of the amplifier, so as to lower the driving capability. For example, when the impedance RL of the speaker 60 is 16Ω, the resistance value of the output resistor R1 is set to be about 200Ω.

The resistance value of the output resistor R1 is desirably set to be within a range from 2 times to 25 times as large as the impedance RL of the speaker 60. By setting the resistance value to be 2 times or above, the voltage amplitude applied to the speaker 60 can be sufficiently lowered. Also, by setting the resistance value to be 25 times or below, band width truncation below 20 kHz can be prevented from being applied by the output resistor R1 and the capacitor of the later stage.

The respective output terminals of the main amplifier 10 and the sub amplifier 20 are connected to the signal output terminal 104. The audio signal SIG20 that is output from the signal output terminal 104 is input into the low-pass filter 50.

The low-pass filter 50 is a filter that removes the high-frequency component of the audio signal SIG20. The low-pass filter 50 includes a first inductor L1 which is disposed in series on the propagation path of the signal and a first capacitor C1 which is disposed between one end of the first inductor L1 and the ground potential. The circuit constant of the first inductor L1 and the first capacitor C1 is determined in accordance with the cut-off frequency fc of the low-pass filter 50. This cut-off frequency fc is set to be a value of 20 kHz or above constituting an audio band, for example, a value of about 30 kHz.

By this low-pass filter 50, the high-frequency component of the one-bit audio signal subjected to pulse width modulation is removed, and an audio signal having an analog amplitude component in accordance with the duty ratio of the pulse width modulation is generated.

Further, the low-pass filter 50 includes a DC block capacitor C2. The DC block capacitor C2 is provided for blocking the DC component of the audio signal SIG20 from being input into the speaker. The audio signal SIG22 from which the DC component has been removed by the DC block capacitor C2 is input into the speaker 60.

The control unit 34 controls the on and off of the main amplifier 10. As described above, the first gate driver circuit 12 of the main amplifier 10 includes an enabling terminal EN1. The control unit 34 controls the on and off of the main amplifier 10 by controlling the enabling signal that is output to the enabling terminal EN1.

While music or the like is being reproduced, the control unit 34 monitors the digital audio signal SIG10 to detect a mute state of the audio signal. Such a mute state is generated, for example, between music tracks of a CD, at an introductory part of a music track, or the like.

Various methods can be considered for determination of the mute state. For example, the mute state can be determined when a signal being at a predetermined level or below continues for a predetermined period of time.

In the mute state, the audio signal SIG22 that is input into the speaker 60 must be fixed to the center level, namely the ground potential. At this time, an audio signal SIG14 subjected to pulse width modulation and having a duty ratio of 50% is output from the ΔΣ modulator 32. During the period of the mute state, the control unit 34 stops the amplification of the audio signal by the first D-class amplifier 14 by setting the enabling signal SEN1 to be at a high level and turning the first gate driver circuit 12 off.

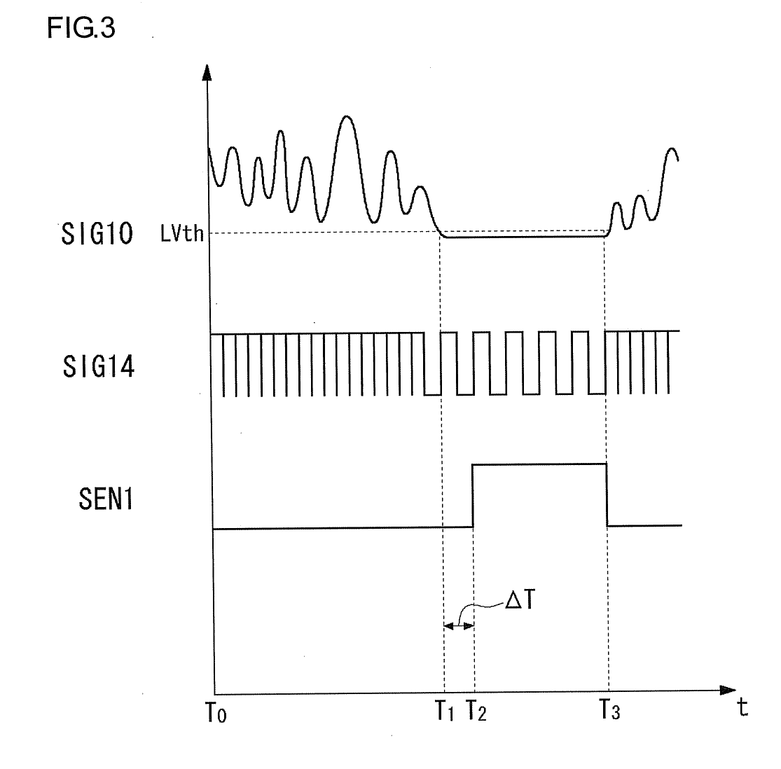

An operation of the audio signal amplifying circuit 100 constructed as shown above will be described. FIG. 3 is a signal waveform view showing an operation state of the audio signal amplifying circuit 100. In FIG. 3, the audio signal SIG10 is shown to have an analog amplitude though actually it is a digital signal.

From the time point T0 to the time point T1, a certain music track MSC1 is being reproduced. The duty ratio of the audio signal SIG14 that is output from the ΔΣ modulator 32 changes with lapse of time in accordance with the music track MSC1. During this period, the control unit 34 maintains the enabling signal SEN1 to be at a low level.

The audio signal SIG14 is output to the main amplifier 10 and the sub amplifier 20, and is amplified by the two D-class amplifiers. The signal amplified by the main amplifier 10 and the sub amplifier 20 is input into the speaker 60 via the low-pass filter 50, whereby the music track MSC1 is output as a sound.

At the time point T1, the music track MSC1 ends to attain the mute state. The control unit 34 monitors the audio signal SIG10. When the amplitude of the audio signal SIG10 comes to be at a predetermined threshold value level LVth or below, the control unit 34 starts measurement of time. When the amplitude of the audio signal SIG10 becomes 0, the duty ratio of the audio signal SIG14 that is output from the ΔΣ modulator 32 is fixed to a constant value of 50%. When the audio signal SIG14 having a fixed duty ratio passes through the low-pass filter 50, it becomes a DC signal and is prevented from being applied to the speaker 60 by the DC block capacitor C2, so that the voltage applied to the speaker 60 will be a ground level. However, in actual cases, the voltage applied to the speaker 60 will not be a complete ground level because of the switching noise or the like generated in the main amplifier 10 and the sub amplifier 20, so that a noise signal is output from the speaker 60.

When the measured time of the mute state in the control unit 34 exceeds a predetermined threshold value ΔT at the time point T2, the control unit 34 switches the enabling signal SEN1 to a high level, and turns the main amplifier 10 off. When the main amplifier 10 is turned off, the audio signal SIG14 is amplified only by the sub amplifier 20, and is output to the speaker 60 via the low-pass filter 50.

Because the main amplifier 10 is turned off, the switching noise is greatly reduced. On the other hand, as described above, since the load driving capability of the sub amplifier 20 is set to be lower than that of the main amplifier 10, the switching noise generated in the sub amplifier 20 is smaller than the switching noise generated from the main amplifier 10. Further, since the amplitude of the audio signal SIG18′ that is output from the sub amplifier 20 is reduced by the output resistor R1, the noise level of the audio signal SIG22 that is output from the low-pass filter 50 will further be reduced.

As a result of this, between the time point T2 and the time point T3, the voltage applied to the speaker 60 will be a signal being close to the ground level and having an extremely small noise component, so that the noise level that is output from the speaker 60 will be greatly reduced.

When a music track MSC2 is started at the time point T3, the control unit 34 immediately makes the enabling signal SEN1 fall to the low level and turns the main amplifier 10 on. When the main amplifier 10 is turned on again at the time point T3, since the first capacitor C1 of the low-pass filter 50 and the DC block capacitor C2 are in a state of being charged with electric charge by the sub amplifier 20, the audio signal SIG14 of the music track MSC2 can be amplified quickly without generating a pop sound noise or the like.

As described above, with the audio signal amplifying circuit 100 according to the present embodiment, the noise that is output from the speaker 60 can be reduced by turning the main amplifier 10 having a high load driving capability off and driving the speaker 60 only by the sub amplifier 20 having a low load driving capability in a mute state.

If both of the main amplifier 10 and the sub amplifier 20 are turned off in a mute state, the noise level of the audio signal SIG20 is reduced, and the noise that is output from the speaker 60 also will be reduced. However, an electric potential difference will be generated between the DC level of the audio signal SIG20 at this time and the audio signal SIG20 at the time when the main amplifier 10 and the sub amplifier 20 are turned on again, a pop sound noise will be generated.

On the other hand, in the audio signal amplifying circuit 100 according to the present embodiment, by continuing to drive the low-pass filter 50 with the sub amplifier 20 in the mute state, generation of the pop sound noise can be prevented when the main amplifier 10 is turned on again.

As shown above, the present invention has been described on the basis of an embodiment. The above-described embodiment is an exemplification, so that it will be understood by those skilled in the art that various modifications can be made in the combination of those constituent elements and treating processes and that those modifications are also within the scope of the present invention.

In the embodiment, description has been given on a case in which the transistor size is reduced so as to lower the driving capability of the sub amplifier 20, and an output resistor R1 is further provided. However, the present invention is not limited to this. For example, the driving capability can be dropped by reducing the transistor size without providing an output resistor R1, or alternatively, the driving capability can be dropped by providing the output resistor R1 while keeping the transistor size to be equivalent to that of the main amplifier 10.

In the embodiment, description has been given on a case in which the control unit 34 detects the mute state by monitoring the audio signal SIG10 that is output from the error correction unit 218. However, the present invention is not limited to this, so that the audio signal SIG12 having passed through the digital filter 30 may be monitored. In other words, the control unit 34 can monitor other signals if the signals are digital signals by which the mute state can be detected under a predetermined condition.

In addition, in the embodiment, description has been given on a case in which the DC block capacitor C2 is placed in the stage posterior to the LC filter as a construction of the low-pass filter 50. However, the present invention is not limited to this, so that the DC block capacitor C2 may be placed immediately posterior to the main amplifier 10 and the sub amplifier 20.

Also, in the embodiment, the audio signal amplifying circuit 100 is constructed in the inside of the DSP 300 integrally with the demodulating unit 216, the error correction unit 218, and others. However, the audio signal amplifying circuit 100 may be singly constructed as one LSI. Which blocks are to be integrated may be determined in accordance with the characteristics required in each block, the electronic devices to be used, and the like.

As an electric device on which the audio signal amplifying circuit 100 according to the embodiment is mounted, it can be widely used in apparatus equipped with means for outputting digital audio signals, such as a DVD player, an MD player, a silicon audio device, a portable telephone terminal, a PDA (Personal Digital Assistance), a digital still camera, and a digital video camera, in addition to the CD player described in the embodiment.

While the preferred embodiments of the present invention have been described using specific terms, such description is for illustrative purposes only, and it is to be understood that changes and variations may be made without departing from the spirit or scope of the appended claims.

1. An audio signal amplifying circuit comprising:
a main amplifier which amplifies an audio signal;
a sub amplifier which is disposed in parallel with the main amplifier and is set to have a lower driving capability than the main amplifier; and
a control unit which controls the on and off of the main amplifier, wherein
the control unit turns the main amplifier off when it is determined that the audio signal is in a mute state.

2. The audio signal amplifying circuit according to claim 1, wherein
the sub amplifier includes an output resistor which is connected in series to an output terminal thereof.

3. The audio signal amplifying circuit according to claim 2, wherein
a resistance value of the output resistor is within a range from 2 times to 25 times as large as an impedance of a speaker connected as a load.

4. The audio signal amplifying circuit according to claim 1, wherein
a size of a transistor constituting the sub amplifier is within a range from 1/1.5 times to 1/10 times as large as a size of a transistor constituting the main amplifier.

5. The audio signal amplifying circuit according to claim 1, wherein
the audio signal is a signal subjected to pulse width modulation and output from a ΔΣ modulator, and
the main amplifier and the sub amplifier are D-class amplifiers.

6. The audio signal amplifying circuit according to claim 1, wherein
the main amplifier includes a D-class amplifier of CMOS (Complementary Metal Oxide Semiconductor) inverter type and a gate driver circuit which controls a gate voltage of a transistor constituting the D-class amplifier, and
the gate driver circuit fixes the gate voltage of the transistor constituting the D-class amplifier in a state in which the main amplifier is off.

7. The audio signal amplifying circuit according to claim 1, wherein
the control unit monitors the digital audio signal modulated by passing through a predetermined digital signal processing, and determines that the digital audio signal is in a mute state when a level of the digital audio signal continues to be lower than a predetermined threshold value level for a predetermined period of time or more.

8. The audio signal amplifying circuit according to claim 1, wherein
the main amplifier, the sub amplifier, and the control unit are integrated into one semiconductor integrated circuit.

9. An electronic device characterized by comprising:
an audio signal amplifying circuit according to claim 1;
a filter which removes a high-frequency component of the audio signal subjected to pulse width modulation and output from the audio signal amplifying circuit; and
a speaker which is driven by an output signal of the filter.
